(19) United States
(12) Patent Application Publication
(10) Pub. No.: US 2026/0089937 A1
(43) Pub. Date: Mar. 26, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chang-Yih Chen, Tainan City (TW); Kuo-Hsing Lee, Hsinchu County (TW); Chun-Hsien Lin, Tainan City (TW); Kun-Szu Tseng, Tainan City (TW); Feng-Yun Cheng, Kaohsiung City (TW); Wei-Chung Sun, Tainan City (TW); Yi-Wen Chen, Chiayi County (TW); Yao-Jhan Wang, Tainan City (TW)

(73) Assignee: UNITED MICROELECTRONICS CORP., Hsin-Chu City (TW)

(21) Appl. No.: 18/931,064

(22) Filed: Oct. 30, 2024

(30) Foreign Application Priority Data
Sep. 23, 2024 (TW) 113136017

(51) Int. Cl. H10B 20/25

(52) U.S. Cl. CPC H10B 20/25

(57) ABSTRACT

A method for fabricating a semiconductor device includes the steps of first forming a first well region in a substrate, forming a shallow trench isolation (STI) adjacent to two sides of the first well region, forming a gate structure on the substrate, forming doped regions adjacent to two sides of the gate structure, and then forming contact plugs on the doped regions. Preferably, a depth of the first well region is less than a depth of the STI and the first well region and the doped regions have different conductive type.

### BACKGROUND OF THE INVENTION

### 1. Field of the Invention

The invention relates to a method for fabricating semiconductor device, and more particularly to a method for fabricating an one-time programmable (OTP) device.

### 2. Description of the Prior Art

Semiconductor memory devices including non-volatile memory devices have been widely used in various electronic devices such as cellular phones, digital cameras, personal digital assistants (PDAs), and other applications. Typically, non-volatile memory devices include multi-time programmable (MTP) memory devices and one-time programmable (OTP) memory devices. In contrast to rewritable memories, OTP memory devices have the advantage of low fabrication cost and easy storage. However, OTP memory devices could only perform a single data recording action such that when certain memory cells of a destined storage block were stored with a writing program, those memory cells could not be written again.

Since current OTP memory devices still have the disadvantage of weak reading current and longer stress time under program mode, how to improve the current architecture for OTP memory devices has become an important task in this field.

### SUMMARY OF THE INVENTION

According to an embodiment of the present invention, a method for fabricating a semiconductor device includes the steps of first forming a first well region in a substrate, forming a shallow trench isolation (STI) adjacent to two sides of the first well region, forming a gate structure on the substrate, forming doped regions adjacent to two sides of the gate structure, and then forming contact plugs on the doped regions. Preferably, a depth of the first well region is less than a depth of the STI and the first well region and the doped regions have different conductive type.

According to another aspect of the present invention, a semiconductor device includes a first well region in a substrate, a shallow trench isolation (STI) adjacent to two sides of the first well region, a gate structure on the substrate, and doped regions adjacent to two sides of the gate structure. Preferably, a depth of the first well region is less than a depth of the STI.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a method for fabricating semiconductor device according to an embodiment of the present invention.

FIG. 5 illustrates a circuit diagram of a diode implemented by OTP capacitor and corresponding operating voltages during read and write operations according to an embodiment of the present invention.

### DETAILED DESCRIPTION

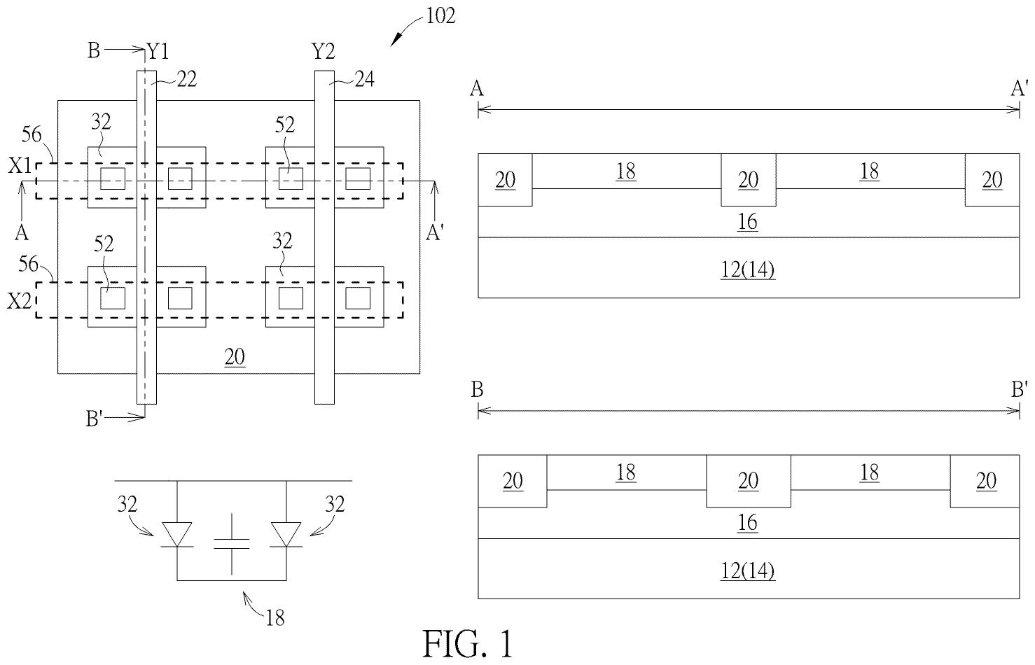

Referring to FIG. 1, FIG. 1 illustrates a method for fabricating a semiconductor device according to an embodiment of the present invention, in which top left portion of FIG. 1 illustrates a top view of an OTP capacitor according to an embodiment of the present invention, bottom left portion of FIG. 1 illustrates a circuit diagram of implementing a diode by using the OTP capacitor, top right portion of FIG. 1 illustrates a cross-section view of the top left portion of FIG. 1 taken along X-direction or the sectional line AA′, and bottom right portion of FIG. 1 illustrates a cross-section view of the top left portion of FIG. 1 taken along Y-direction or the sectional line BB′. As shown in FIG. 1, a substrate 12 such as a silicon substrate or silicon-on-insulator (SOI) substrate is provided and a core region and an OTP capacitor region 102 are defined on the substrate 12, in which the core region is used for preparing active devices such as a metal-oxide semiconductor (MOS) transistor in the later process while the OTP capacitor region 102 is used for fabricating an OTP capacitor.

Next, a deep well such as a deep n-well 14 is formed in the substrate 12, a first well such as a p-well 16 is formed on top of the deep n-well 14, and then a second well such as a n-well 18 is formed on top of the p-well 16, in which the n-well 18 preferably serves as a bottom electrode for the OTP capacitor in the later process. In this embodiment, the first well and the second well include dopants having opposite conductive type. For instance, despite the deep well includes a deep n-well 14, first well includes a p-well 16, and the second well includes a n-well 18 in this embodiment, according to other embodiment of the present invention, it would also be desirable to implant dopants with opposite conductive type for the above deep well and well regions such as having a deep p-well for the deep well, a n-well for the first well, and a p-well for the second well, which is also within the scope of the present invention.

Next, a photo-etching process could be conducted to remove part of the substrate 12 for forming a plurality of trenches, a flowable chemical vapor deposition (FCVD) process is conducted to form an insulating layer made of silicon oxide and fill the trenches, and a planarizing process such as chemical mechanical polishing (CMP) process is conducted to remove part of the insulating layer so that the top surface of the remaining the insulating layer is substantially even with the top surface of the substrate 12 to form a shallow trench isolation (STI) 20.

It should be noted that the p-well 16 formed at this stage is preferably a well region slightly deeper than the STI 20 while the n-well 18 is a shallow well as the depth of the STI 20 is between the depths of the p-well 16 and n-well 18. For instance, the depth of the p-well 16 is slightly greater than the depth of the STI 20, the depth of the n-well 18 is slightly less than the depth of the STI 20, or if viewed from another perspective the bottom surface of the p-well 16 is slightly lower than the bottom surface of the STI 20 and the bottom surface of the n-well 18 is slightly higher than the bottom surface of the STI 20 while the n-well 18 does not extend downward along sidewall of the STI 20 to the bottom surface of the STI 20.

In this embodiment, the depth of the n-well 18 is preferably greater than half of the overall depth of the STI 20 or more preferably greater than 60% of the entire depth of the STI 20, greater than 70% of the entire depth of the STI 20, or most preferably between 70% to 80% of the entire depth of the STI 20, in which the depth of the STI 20 is between 220-280 nm or most preferably at 250 nm and the depth of the n-well 18 is between 150-200 nm or most preferably at 180 nm. In other words, the bottom surface of the n-well 18 is slightly lower than half or more of the depth of the STI 20 but still higher than the bottom surface of the STI 20.

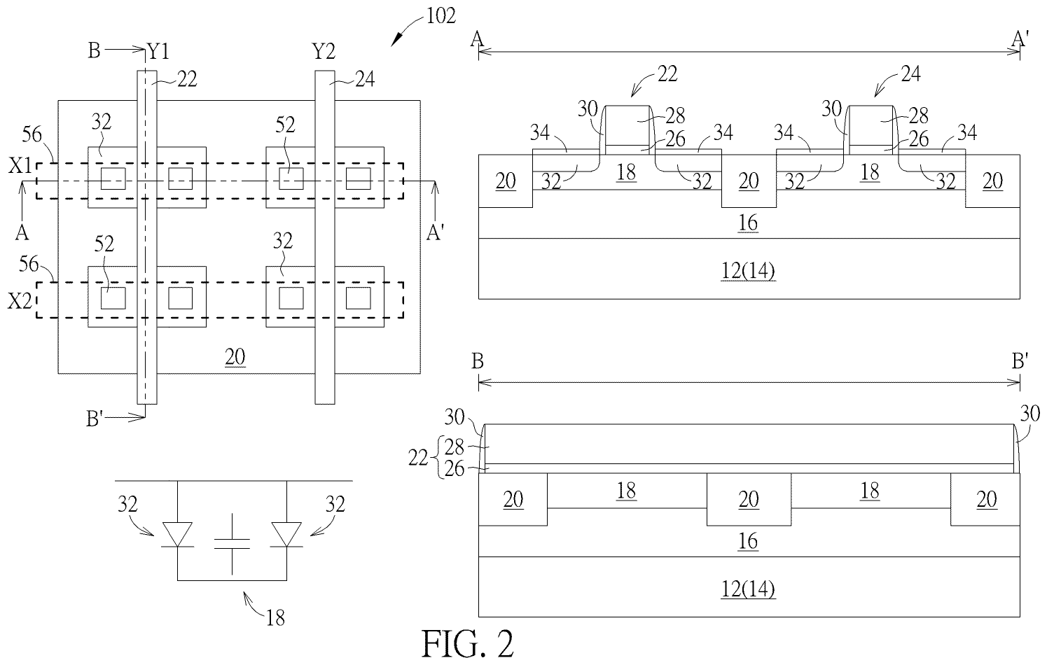

Referring to FIG. 2, FIG. 2 illustrates a method for fabricating a semiconductor device following FIG. 1, in which top left portion of FIG. 2 illustrates a top view of an OTP capacitor according to an embodiment of the present invention, bottom left portion of FIG. 2 illustrates a circuit diagram of implementing a diode by using the OTP capacitor, top right portion of FIG. 2 illustrates a cross-section view of the top left portion of FIG. 2 taken along X-direction or the sectional line AA′, and bottom right portion of FIG. 2 illustrates a cross-section view of the top left portion of FIG. 2 taken along Y-direction or the sectional line BB′. As shown in FIG. 2, gate structures 22, 24 are then formed on the substrate 12, in which the gate structures 22, 24 on the OTP capacitor region 102 could be serving as top electrodes for OTP capacitors and the formation of the gate structures 22, 24 could be accomplished by a gate first process, a high-k first approach from gate last process, or a high-k last approach from gate last process.

Since this embodiment pertains to a high-k last approach, a gate dielectric layer 26 made of silicon oxide, a gate material layer 28 made of polysilicon, and a selective hard mask (not shown) could be formed sequentially on the substrate 12, and a photo-etching process is then conducted by using a patterned resist (not shown) as mask to remove part of the gate material layer 28 and part of the gate dielectric layer 26 through single or multiple etching processes. After stripping the patterned resist, gate structures 22, 24 each made of a patterned gate dielectric layer 26 and a patterned material layer 28 are formed on the substrate 12, in which the patterned gate material layer 28 could be serving as gate electrodes for active devices on the transistor region and top electrodes for the OTP capacitor.

Next, at least a spacer 30 is formed on the sidewalls of each of the gate structures 22, 24 and then doped regions 32 or source/drain regions are formed in the substrate 12 adjacent to two sides of the gate structures 22, 24. In this embodiment, the spacer 30 could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof. The doped regions 32 or source/drain regions could include n-type dopants or p-type dopants depending on the type of device being fabricated. For instance, each of the doped region 32 in this embodiment preferably includes p-type dopants or a p+ region, but not limited thereto. Next, a salicide process is conducted to form silicides 34 on the surface of the substrate 12 adjacent to two sides of the gate structures 22, 24.

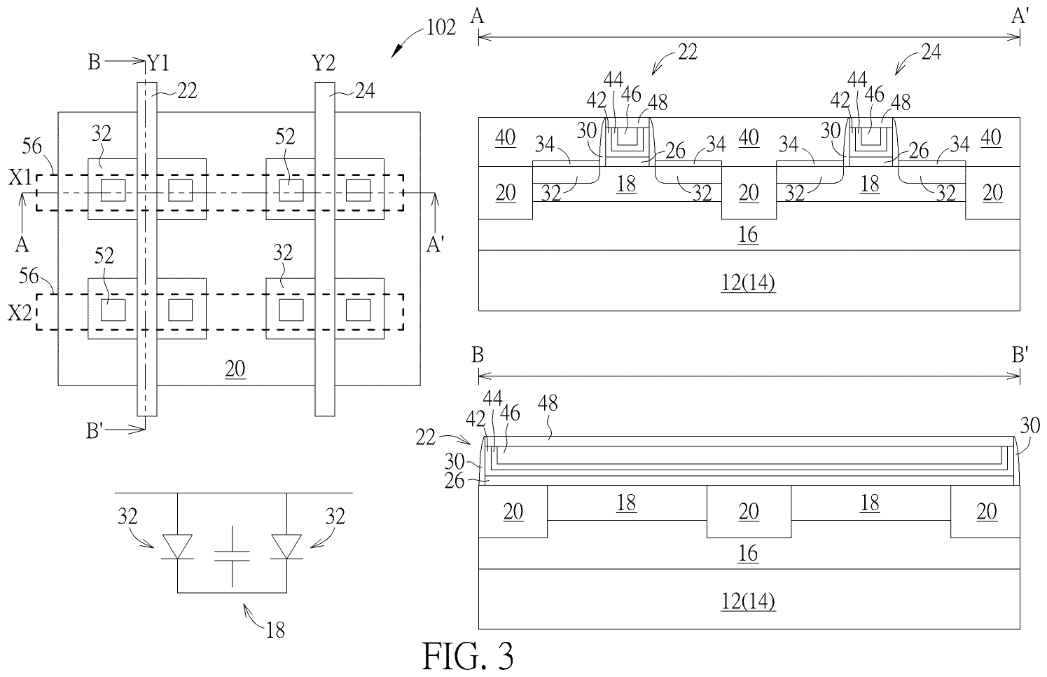

Referring to FIG. 3, FIG. 3 illustrates a method for fabricating a semiconductor device following FIG. 2, in which top left portion of FIG. 3 illustrates a top view of an OTP capacitor according to an embodiment of the present invention, bottom left portion of FIG. 3 illustrates a circuit diagram of implementing a diode by using the OTP capacitor, top right portion of FIG. 3 illustrates a cross-section view of the top left portion of FIG. 3 taken along X-direction or the sectional line AA′, and bottom right portion of FIG. 3 illustrates a cross-section view of the top left portion of FIG. 3 taken along Y-direction or the sectional line BB′.

As shown in FIG. 3, an interlayer dielectric (ILD) layer 40 made of silicon oxide is formed on the gate structures 22, 24 and the STI 20, and a planarizing process such as chemical mechanical polishing (CMP) process is conducted to remove part of the ILD layer 40 for exposing the gate material layer 28 so that the top surfaces of the gate material layer 28 and the ILD layer 40 are coplanar.

Next, a replacement metal gate (RMG) process is conducted to transform the gate structures 22, 24 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the gate material layers 28 and even the gate dielectric layer 26 from gate structures 22, 24 for forming recesses (not shown) in the ILD layer 40. Next, a high-k dielectric layer 42, a work function metal layer 44, and a low resistance metal layer 46 are formed in the recesses, and a planarizing process such as CMP is conducted to remove part of low resistance metal layer 46, part of work function metal layer 44, and part of the high-k dielectric layer 42 so that the top surfaces of the U-shape high-k dielectric layer 42, the U-shape work function metal layer 44, the low resistance metal layer 46, and the ILD layer 40 are coplanar. Preferably, the high-k dielectric layer 42, the work function metal layer 44, and the low resistance metal layer 46 altogether constitute a gate electrode for each of the transistors or devices.

In this embodiment, the high-k dielectric layer 42 is preferably selected from dielectric materials having dielectric constant (k value) larger than 4. For instance, the high-k dielectric layer 42 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 44 is formed for tuning the work function of the metal gate in accordance with the conductivity of the device. For an NMOS transistor, the work function metal layer 44 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 44 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 44 and the low resistance metal layer 46 may include titanium (Ti), titanium nitride (TiN), tantalum (Ta) or tantalum nitride (TaN). Furthermore, the material of the low-resistance metal layer 46 may include copper (Cu), aluminum (Al), titanium aluminum (TiAl), cobalt tungsten phosphide (CoWP) or any combination thereof. Since the transformation of dummy gates into metal gates through RMG process is well known to those skilled in the art, the details of which are not explained herein for the sake of brevity. Next, part of the high-k dielectric layer 42, part of the work function metal layer 44, and part of the low resistance metal layer 46 are removed to form recesses (not shown), and a hard mask 48 is formed into each of the recesses so that the top surfaces of the hard masks 48 and the ILD layer 40 are coplanar. Preferably the hard masks 48 could include SiO₂, SiN, SiON, SiCN, or combination thereof.

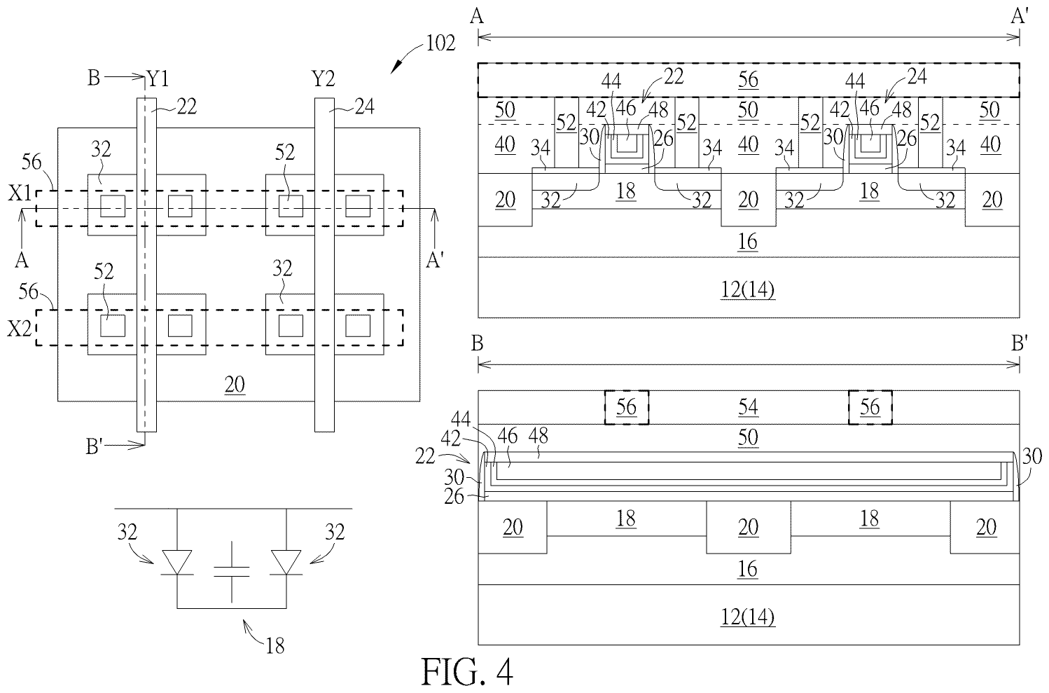

Referring to FIG. 4, FIG. 4 illustrates a method for fabricating a semiconductor device following FIG. 3, in which top left portion of FIG. 4 illustrates a top view of an OTP capacitor according to an embodiment of the present invention, bottom left portion of FIG. 4 illustrates a circuit diagram of implementing a diode by using the OTP capacitor, top right portion of FIG. 4 illustrates a cross-section view of the top left portion of FIG. 4 taken along X-direction or the sectional line AA′, and bottom right portion of FIG. 4 illustrates a cross-section view of the top left portion of FIG. 4 taken along Y-direction or the sectional line BB′.

As shown in FIG. 4, another ILD layer 50 could be formed on the gate structures 22, 24 made of metal gates and ILD layer 40 and a photo-etching process is conducted by using a patterned mask (not shown) to remove part of the ILD layers 40, 50 for forming contact holes (not shown) exposing the doped regions 32 or silicides 34. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs 52 electrically connecting the doped regions 32 or silicides 34.

Next, a metal interconnective process could be conducted by first forming an inter-metal dielectric (IMD) layer 54 on the ILD layer 50 and then conducting one or more photo-etching processes to remove part of the IMD layer 54 for forming contact holes (not shown). Next, conductive materials are deposited into the contact holes, a planarizing process such as CMP is conducted to remove part of the conductive materials for forming a metal interconnection 56 connecting the contact plugs 52 adjacent to two sides of the gate structures 22, 24, and then an optional stop layer (not shown) is formed on the surface of the metal interconnection 56. Similar to the aforementioned contact plugs 52, the metal interconnection 56 could be fabricated according to a single damascene process or dual damascene process. For instance, the metal interconnection 56 could further include a barrier layer and a metal layer, in which the barrier layer could be selected from the group consisting of titanium (Ti), titanium nitride (TiN), tantalum (Ta), and tantalum nitride (TaN) and the metal layer could be selected from the group consisting of tungsten (W), copper (Cu), aluminum (Al), titanium aluminide (TiAl), and cobalt tungsten phosphide (CoWP). This completes the fabrication of an OTP capacitor according to an embodiment of the present invention.

Referring again to FIG. 4, FIG. 4 further illustrates a structural view of integrating an OTP capacitor and diode according to an embodiment of the present invention. As shown on the top left portion of FIG. 4, the OTP capacitor includes two sets of OTP capacitors connected in parallel, in which each of the OTP capacitor such as the left one on top right portion of FIG. 4 includes a STI 20 disposed in the substrate 12 for separating adjacent OTP capacitors, a n-well 18 disposed in the substrate 12 between the STI 20, a p-well 16 disposed under the n-well 18, a deep n-well 14 disposed in the substrate 12 under the p-well 16, a gate structure 22 disposed on the substrate 12, doped regions 32 disposed in the substrate 12 adjacent to two sides of the gate structure 22, silicides 34 disposed on the surface of the doped regions 32, and contact plugs 52 connecting the doped regions 32 and the upper level metal interconnections 56. Preferably, the gate structures 22, 24 shown on right portion of FIG. 4 are essentially conductive lines Y1, Y2 extending along Y-direction on left portion of FIG. 4 while the metal interconnections 56 connecting the contact plugs 52 or doped regions 32 shown on right portion of FIG. 4 are conductive lines X1, X2 extending along X-direction on left portion of FIG. 4.

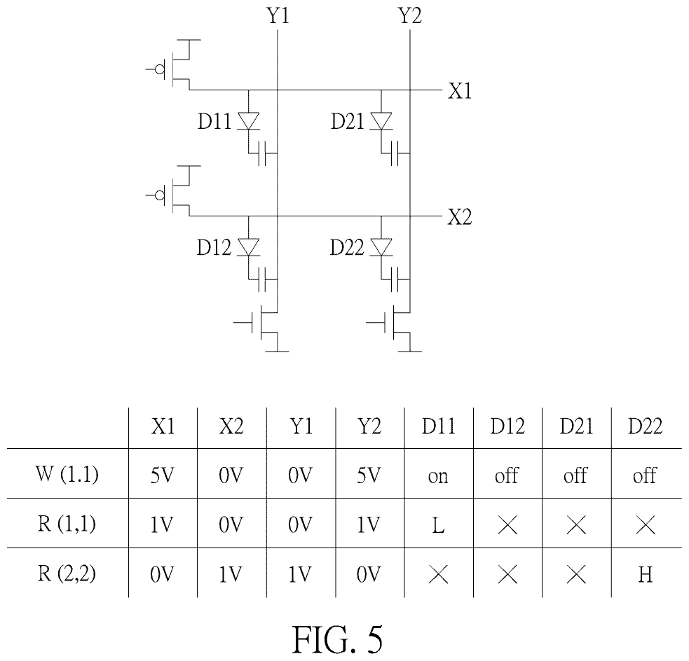

In this embodiment, the n-well 18 disposed in the substrate 12 preferably serves as a bottom electrode for the OTP capacitor, the gate dielectric layer 26 and/or high-k dielectric layer 42 serve as a capacitor dielectric layer for the OTP capacitor, and the work function metal layer 44 and/or low resistance metal layer 46 serve as a top electrode for the OTP capacitor. Moreover, each of the OTP capacitors is further used to implement a diode structure such as the diodes D11, D11, D21, D22 shown in FIG. 5. For instance, the n-well 18 in the substrate 12 could also be serving as a cathode while the doped regions 32 having p+ dopants could be serving as an anode for the diode structure, in which the n-well 18 in this embodiment includes no other doped regions except the doped regions 32. Evidently shown in the cross-section views as well as the top view on top left portion and circuit diagram on bottom left portion of FIG. 2, the anode of the diode is connected to outer circuit through the doped regions 32, the contact plugs 52, and the metal interconnections 56 while the cathode of the diode is connected to outside circuit through the n-well 18, the gate dielectric layer 26, and the gate structure 22.

Referring to FIG. 5, FIG. 5 illustrates a circuit diagram of a diode implemented by OTP capacitor and corresponding operating voltages during read and write operations according to an embodiment of the present invention. As shown in FIG. 5, the present embodiment includes four sets of diodes implemented by the aforementioned OTP capacitors, including the diode D11 connected to the conductive lines Y1, X1, the diode D12 connected to the conductive lines Y1, X2, the diode D21 connected to the conductive lines Y2, X1, and the diode D22 connected to the conductive lines Y2, X2.

First, if a write operation (W) were to be conducted on the diode D11 through the conductive lines Y1, X1, the conductive line X1 is set at 5V, the conductive lines X2 and Y2 are maintained at 0V, and the conductive line Y2 is set at 5V so that the voltage difference would then keep the diode D11 at on state while the remaining diodes D12, D21, D22 are not written and remained at off state. Next, if a read operation (R) were to be conducted on the diode D11 through the conductive lines Y1, X1, since the diode D11 has already been written, the state of the diode D11 is preferably kept at low resistance (L) state. If the diode D22 were read through the conductive lines Y2, X2, since the diode D22 has not be written, the state of the diode D22 is maintained at high resistance (H) state. Typically, higher voltage is needed during write operation as lower voltage is commonly used during read operation, hence the voltage is often kept at 5V during write operation while the voltage is kept at 1V during read operation in this embodiment.

Overall, the present invention discloses an approach of using OTP capacitor to implement a diode device, which first forms a deep well such as a deep n-well 14 in the substrate 12, forms a first well such as p-well 16 on top of the deep n-well 14, forms a second well such as n-well 18 on the p-well 16, forms a STI 20 in the substrate, forms a gate structure 22 on the substrate, and then forms doped regions 32 or source/drain regions in the substrate adjacent to two sides of the gate structure. Preferably, the n-well 18 directly under the gate structure 22 and between the STI 20 is a shallow well region, which as a depth at approximately 70% to 80% of the entire depth of the STI 20 or the bottom surface of the n-well 18 is lower than half of the depth of the STI but still higher than the bottom surface of the STI.

Typically, if cathodes (such as n-well 18) between adjacent diodes such as the diode D11 and the diode D12 were shared an interference is likely to occur, hence the present invention keeps the depth of a cathode or n-well 18 at a substantially shallower range such as slightly higher than the bottom surface of the STI so that interference between OTP capacitors or diodes could be minimized. According to a preferred embodiment of the present invention, this design not only increases density of the device as well as read and write current over current MOS transistors, but also reduces time required during read and write operation thereby improving overall performance of the device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a first well region in a substrate;
forming a shallow trench isolation (STI) adjacent to two sides of the first well region, wherein a depth of the first well region is less than a depth of the STI;
forming a gate structure on the substrate; and
forming doped regions adjacent to two sides of the gate structure.

2. The method of claim 1, further comprising forming a second well region under the first well region.

3. The method of claim 2, wherein the first well region and the second well region comprise different conductive type.

4. The method of claim 2, wherein the doped regions and the second well region comprise same conductive type.

5. The method of claim 1, wherein the first well region and the doped regions comprise different conductive type.

6. The method of claim 1, further comprising forming contact plugs on the doped regions.

7. A semiconductor device, comprising:
a first well region in a substrate;
a shallow trench isolation (STI) adjacent to two sides of the first well region, wherein a depth of the first well region is less than a depth of the STI;
a gate structure on the substrate; and
doped regions adjacent to two sides of the gate structure.

8. The semiconductor device of claim 7, further comprising a second well region under the first well region.

9. The semiconductor device of claim 8, wherein the first well region and the second well region comprise different conductive type.

10. The semiconductor device of claim 8, wherein the doped regions and the second well region comprise same conductive type.

11. The semiconductor device of claim 7, wherein the first well region and the doped regions comprise different conductive type.

12. The semiconductor device of claim 7, further comprising contact plugs on the doped regions.
